(19) United States
(12) Patent Application Publication
(10) Pub. No.: US 2015/0003017 A1
(43) Pub. Date: Jan. 1, 2015

(54) SYSTEM FOR REGULATING THE TEMPERATURE OF AN ASSEMBLY OF ELECTRONIC COMPONENTS OR FOR RECOVERING THE THERMAL ENERGY DISSIPATED BY AN ASSEMBLY OF ELECTRONIC COMPONENTS

(71) Applicant: THALES, Neuilly-sur-Seine (FR)

(72) Inventors: Christian Tantolin, Lumbin (FR); Claude Sarno, Etoile Sur Rhone (FR)

(21) Appl. No.: 14/365,084

(22) PCT Filed: Dec. 6, 2012
(86) PCT No.: PCT/EP2012/074603

§ 371 Date: Jun. 12, 2014

(30) Foreign Application Priority Data
Dec. 13, 2011 (FR) 1103820

(51) Int. Cl. H05K 7/20

(52) U.S. Cl. CPC H05K 7/20009; H05K 2007/20118
USPC 361/701

(57) ABSTRACT

A system for regulating the temperature of printed circuit boards comprises a first assembly of at least one Peltier element, for regulating the temperature of a second assembly of at least one electronic component or for harvesting thermal energy dissipated by the second assembly. At least one Peltier element of the first assembly is coupled to first heat-exchanging means that are coupled to at least one electronic component of the second assembly, and to second heat-exchanging means allowing thermal energy given off from at least one Peltier element of the first assembly to be dissipated.

The invention relates to a system for regulating the temperature of printed circuit boards, and more particularly to a system for regulating temperature and harvesting thermal energy comprising at least one Peltier element.

A printed circuit board is formed of at least one printed circuit comprising electronic components. When started up, certain sensitive electronic components need to be heated to a certain temperature. In operation, other electronic components generate heat that needs to be evacuated from the electronic device. In the case of power supply boards, for example, it is advantageous to harvest the thermal energy dissipated by the electronic components, and to convert it into electrical energy in order to increase conversion efficiency.

It is known to associate at least one Peltier element with an electronic component in order to regulate a temperature or harvest thermal energy dissipated by an electronic component.

A Peltier element takes the form of a succession of P-N junctions mounted in series and brazed between two ceramic plates, namely a cold plate and a hot plate.

Document WO 2009/152887 is an international patent application. It describes the use of a Peltier element to regulate a temperature of a component or to harvest thermal energy dissipated by an electronic component.

In order to cool or heat an electronic component or harvest the thermal energy dissipated by an electronic component using a Peltier element, said element is placed on the top part of the component in question.

When it is necessary to heat a component before it is started up, a Peltier element is associated with the electronic component by placing the hot face of the Peltier element in contact with said component.

In the case where it is necessary to cool an electronic component, a Peltier element is then placed with its cold face making contact with said component.

If it is required to harvest dissipated thermal energy, a Peltier element is placed with its hot face making contact with said component. The heat flux that flows through the Peltier element generates an electrical voltage.

In the cited document, the Peltier element comprises an electrical power supply the power of which depends on the maximum dissipated, harvested or delivered energy.

One drawback of the embodiment proposed in document WO 2009/152887 is that it requires a Peltier element to be associated with each electronic component, it cannot be used in the case where the heat given off comes from a large number of electronic components, individually generating little thermal energy, on a printed circuit board.

One aim of the invention is to regulate the temperature of a printed circuit board comprising a plurality of electronic components, or to harvest the thermal energy dissipated by a plurality of electronic components distributed over a printed circuit board.

According to one aspect of the invention, a system is provided for regulating the temperature of printed circuit boards, characterized in that it comprises a first assembly of at least one Peltier element, for regulating the temperature of a second assembly of at least one electronic component or for harvesting thermal energy dissipated by said second assembly, the first assembly being on the same printed circuit board as the second assembly, at least one Peltier element of the first assembly being coupled to first heat-exchanging means that are coupled to at least one electronic component of the second assembly, and to second heat-exchanging means allowing thermal energy given off from at least one Peltier element of the first assembly to be dissipated.

Associating at least one Peltier element with a plurality of electronic components makes it possible to regulate the temperature or harvest the thermal energy of electronic components dispersed over the printed circuit board and exchanging little thermal energy when they are considered individually, for example.

The invention will be better understood on studying a few embodiments described by way of completely nonlimiting example and illustrated by the appended drawings, in which:

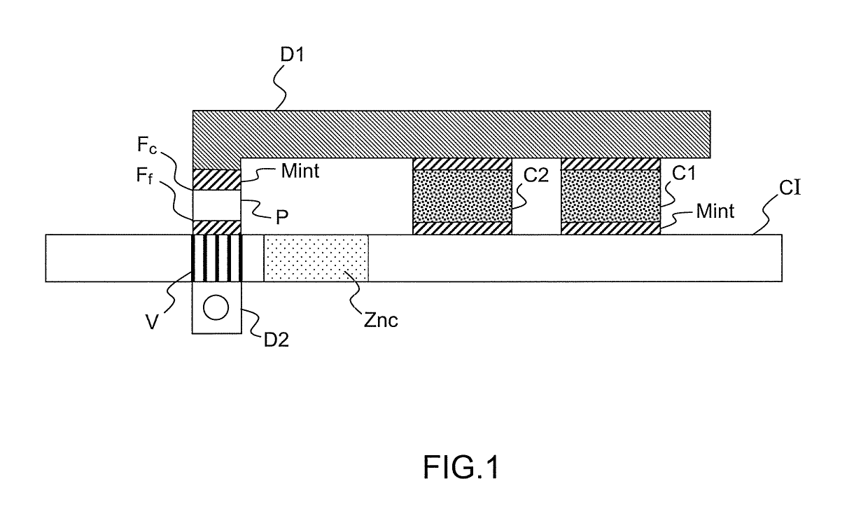

FIG. 1 shows a system for regulating temperature or harvesting dissipated thermal energy in an operating mode for heating electronic components, according to one aspect of the invention.

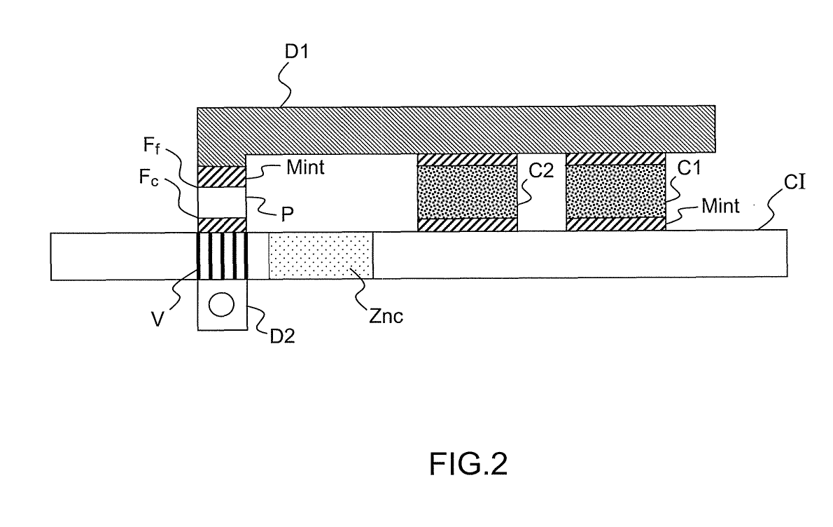

FIG. 2 shows a system for regulating temperature or harvesting dissipated thermal energy in an operating mode for cooling electronic components, according to one aspect of the invention.

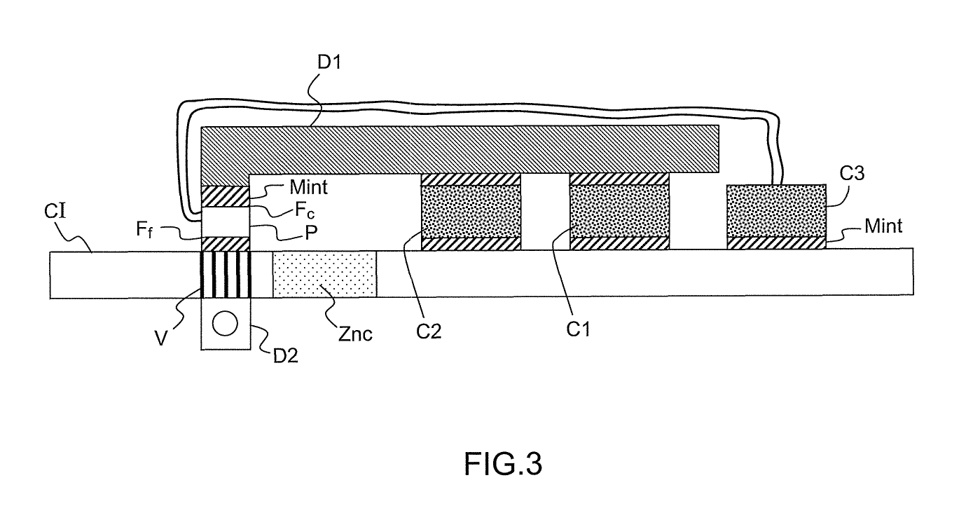

FIG. 3 shows a system for regulating temperature or harvesting dissipated thermal energy in an operating mode for harvesting the thermal energy dissipated by electronic components in order to convert said energy into electrical energy, according to one aspect of the invention.

A printed circuit board C1 for example comprises at least two electronic components C1, C2 to be heated using a Peltier element P, which components are coupled to a first heat exchanger D1 connecting the electronic components, and to a second heat exchanger D2 coupled to a cooling system (not shown in FIGS. 1, 2 and 3).

In FIG. 1, the Peltier element P and its electrical power supply system (not shown in the figure) are fixed on the same printed circuit board C1 as the electronic components C1, C2 to be heated, the Peltier element P being coupled to first heat-exchanging means. Thus, the dimensions of the Peltier element P are independent of the number or size of the electronic components C1, C2 to be regulated.

Advantageously, the Peltier element P comprises an innovative material based on Bi₂Te₃, ZnₓSn_{y}O_{z} or RₓCo₄Sb₁₂ deposited in the form of nanolayers, this allowing the coefficient of performance (COP) of this type of Peltier element P to be multiplied by more than two relative to a conventional Peltier element P.

The power that the power supply of the Peltier element P must supply depends on the average thermal energy harvested from the electronic components C1, C2 and not on the maximum energy required by one of the electronic components C1, C2.

In order to prevent the transfer of heat from the Peltier element P to the electronic components C1, C2 fixed on the same printed circuit board C1 as the Peltier element P, the printed circuit board C1 comprises a zone Znc, located between the Peltier element P and the rest of the printed circuit board C1, containing a thermally insulating material, advantageously an epoxy polymer having a thermal conductivity of 0.3 W.m⁻¹.K⁻¹. In other words, the Peltier element P is thermally isolated from the rest of the printed circuit board C1.

A first heat-exchanging means D1 connects the components C1, C2 to be heated to the hot face Fc of the Peltier element P in order to harvest thermal energy via the Peltier element P and to transmit said energy to the components C1, C2 to be heated. The temperature regulating system thus produced solicits the Peltier element P associated with the electronic components C1 and C2 uniformly.

The first heat-exchanging means D1 may comprise very highly thermally conductive materials, such as aluminum, graphite or diamond.

The first heat-exchanging means D1 may advantageously be a two-phase system, for example a heat pipe or a heat spreader.

A system of thermal vias V allows the heat dissipated by the Peltier element P to be transferred from the frontside to the backside of the printed circuit board C1.

The thermal vias V may be copper inserts or micro-vias.

A second heat-exchanging means D2 connects the backside of the printed circuit board C1 to a cooling system (not shown in FIG. 1) allowing thermal energy dissipated by the Peltier element P to be evacuated.

Advantageously, the second heat-exchanging means D2 may be a two-phase system, thereby making it possible to dissipate the high heat flux densities that may be encountered in the case where a Peltier element P based on the innovative materials mentioned above is used.

The Peltier element and the electronic components may be brazed, soldered or fastened using interface materials Mint. Said interface materials Mint are placed at all the interfaces via which heat is exchanged, for example between an electronic component and the first heat-exchanging means D1 or between the Peltier element P and the first and second heat-exchanging means D1 and D2, in order to limit thermal contact resistances.

When this embodiment of the system for regulating temperature or harvesting electrical energy is used in a heating mode, it is possible to heat only components sensitive to cold start-up, for example, rather than all of the printed circuit board as is the case with a resistive heating system.

In addition, when the system for regulating temperature or harvesting thermal energy is used in its heating mode, it has a higher efficiency than resistive heaters, thereby making it possible to lower energy consumption and decrease the size of the electrical power supply, thereby saving space.

When the system for regulating temperature or harvesting electrical energy is used in a cooling mode to cool electronic components, as shown in FIG. 2, it is used in a similar configuration.

The electrical current is oriented so as to place the cold face Ff of the Peltier element in contact with the first heat-exchanging means D1, in this case the cold face Ff and the hot face Fc are reversed relative to the case shown in FIG. 1.

The second heat-exchanging means D2, advantageously a two-phase system, allows the heat dissipated by the Peltier element to the evacuated to a point distant from the components C1, C2 and thus indirect heating of electronic components to be prevented.

When the system for regulating temperature or harvesting electrical energy is used in a harvesting mode to harvest heat given off by electronic components, as shown in FIG. 3, it is used in a similar configuration.

The electrical current is oriented so as to place the hot face Fc of the Peltier element P in contact with the first heat-exchanging means D1, in this case the cold face Ff and the hot face Fc are placed identically to the case shown in FIG. 1.

The second heat-exchanging means D2, advantageously a two-phase system, allows the heat dissipated by the Peltier element to be evacuated to a point distant from the components C1, C2 and thus indirect heating of electronic components to be prevented.

The heat that passes through the Peltier element allows an electrical voltage to be generated, which voltage may be used to supply electrical power to an electronic component C3, possibly mounted on the same printed circuit board, in order to improve overall efficiency or to provide a partial emergency power supply during a power cut, good use being made of the high thermal inertia, about a few minutes, of the printed circuit board.

1. A system for regulating the temperature of printed circuit boards, comprising: a first assembly of at least one Peltier element, for regulating the temperature of a second assembly of at least one electronic component or for harvesting thermal energy dissipated by said second assembly, the first assembly being fixed on the same printed circuit board as the second assembly, at least one Peltier element of the first assembly being coupled to first heat-exchanging means that are coupled to at least one electronic component of the second assembly, and to second heat-exchanging means allowing thermal energy given off from at least one Peltier element of the first assembly to be dissipated.

2. The system as claimed in claim 1, in which the first assembly comprises only one Peltier element.

3. The system as claimed in claim 1, in which said Peltier element is fixed on the same printed circuit board as said components.

4. The system as claimed in claim 1, in which said Peltier element comprises an electrical power supply the power of which depends on an average delivered thermal energy dissipated by said components of the second assembly.

5. The system as claimed in claim 1, in which said Peltier element allowing an average thermal energy dissipated by the second assembly to be converted into electrical energy is suitable for supplying electrical power to other electronic components on the printed circuit board.

6. The system as claimed in claim 1, comprising at least one Peltier element fixed on a printed circuit board and thermally isolated from the electronic components of the second assembly, which components are fixed on the same printed circuit board, so as not to transfer heat to them.
